(19) United States
(12) Patent Application Publication
(10) Pub. No.: US 2026/0123121 A1
(43) Pub. Date: Apr. 30, 2026

(54) INFRARED LIGHT-EMITTING DIODES WITH FILTER STRUCTURES

(71) Applicant: CreeLED, Inc., Durham, NC (US)

(72) Inventors: David Suich, Durham, NC (US); Austin Spencer, Durham, NC (US); Michael Check, Holly Springs, NC (US); Joseph G. Sokol, Durham, NC (US); Colin Blakely, Raleigh, NC (US)

(21) Appl. No.: 18/928,576

(22) Filed: Oct. 28, 2024

(51) Int. Cl. H01L 33/60

(52) U.S. Cl. CPC H10H 20/856

(57) ABSTRACT

Solid-state lighting devices and more particularly infrared light-emitting diodes (LEDs) with filter structures are disclosed. Filter structures include long-pass filters configured to pass wavelength-converted light while reflecting light from underlying LED chips. Filter structures further include various dual band-pass filters and multiple band-pass filters in combination with long-pass filters that provide targeted emissions in specific infrared wavelength bands. Filter structures may be provided as part of cover structures over LED chips as various multiple-layer dielectric layer sequences. Infrared light-absorbing particles may be provided in combination with filter structures to provide further targeted emissions.

### FIELD OF THE DISCLOSURE

The present disclosure relates to solid-state lighting devices and more particularly to infrared light-emitting diodes with filter structures.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LED technology is increasingly being developed for providing general illumination in a variety of environments. LED manufacturers must balance multiple application tradeoffs including efficacy, longevity, spectral optimization, and optical distribution in view of potential environmental impacts.

The art continues to seek improved LEDs and solid-state lighting devices having desirable illumination characteristics capable of overcoming challenges associated with conventional lighting devices.

### SUMMARY

The present disclosure relates to solid-state lighting devices and more particularly to infrared light-emitting diodes (LEDs) with filter structures. Filter structures include long-pass filters configured to pass wavelength-converted light while reflecting light from underlying LED chips. Filter structures further include various dual band-pass filters and multiple band-pass filters in combination with long-pass filters that provide targeted emissions in specific infrared wavelength bands. Filter structures may be provided as part of cover structures over LED chips as various multiple-layer dielectric layer sequences. Infrared light-absorbing particles may be provided in combination with filter structures to provide further targeted emissions.

In one aspect, an LED package comprises: at least one LED chip configured to emit light with a first peak wavelength in a range from 430 nanometers (nm) to 480 nm; a lumiphoric material arranged to convert at least a portion of the light of the first peak wavelength to light with a second peak wavelength that is in a range from 700 nm to 4000 nm; a first filter structure on the lumiphoric material, the first filter structure configured to be more reflective than transmissive to light having the first peak wavelength and more transmissive than reflective to light having the second peak wavelength; and a second filter structure on the first filter structure, the second filter structure configured to be more transmissive than reflective to a first wavelength band of light that passes through the first filter structure and more reflective than transmissive to other wavelengths of light that pass through the first filter structure. The LED package may further comprise a support element on the at least one LED chip, wherein the first filter structure and the second filter structure are on opposing sides of the support element. In certain embodiments, the first filter structure and the second filter structure are separated by a thickness of the support element, and wherein the thickness of the support element is in a range from 100 microns (μm) to 600 μm. In certain embodiments, the support element comprises light-absorbing particles that absorb a portion of the light with the second peak wavelength that is outside of the first wavelength band. In certain embodiments, the light-absorbing particles comprise at least one of doped tungsten oxide, doped tin oxide, and lanthanum hexaboride. The LED package may further comprise a third filter structure on a same side of the support element as the second filter structure, the third filter structure configured to be more transmissive than reflective to a second wavelength band of light that passes through the first filter structure and more reflective than transmissive to other wavelengths of light outside the second wavelength band that pass through the first filter structure. In certain embodiments, the second filter structure is further configured to be more transmissive than reflective to a second wavelength band of light that passes through the first filter structure and more reflective than transmissive to other wavelengths of light that are outside the first wavelength band and the second wavelength band. In certain embodiments, the second filter structure is further configured to be more transmissive than reflective to a third wavelength band of light that passes through the first filter structure and more reflective than transmissive to other wavelengths of light that are outside the first wavelength band, the second wavelength band, and the third wavelength band. The LED package may further comprise a support element on the at least one LED chip, wherein the first filter structure and the second filter structure are on a same side of the support element. The LED package may further comprise a third filter structure on the same side of the support element as the first filter structure and the second filter structure, the third filter structure configured to be more transmissive than reflective to a second wavelength band of light that passes through the first filter structure and more reflective than transmissive to other wavelengths of light that pass through the first filter structure.

In another aspect, an LED package comprises: at least one LED chip configured to emit light with a first peak wavelength in a range from 430 nanometers (nm) to 480 nm; a lumiphoric material arranged to convert at least a portion of the light of the first peak wavelength to light with a second peak wavelength that is in a range from 700 nm to 4000 nm; a first filter structure on the lumiphoric material, the first filter structure configured to be more reflective than transmissive to light having the first peak wavelength and more transmissive than reflective to light having the second peak wavelength; and light-absorbing particles configured to absorb a portion of the light with the second peak wavelength. The LED package may further comprise an encapsulant on the at least one LED chip, wherein the light-absorbing particles are within the encapsulant. The LED package may further comprise a support element on the at least one LED chip, wherein the first filter structure is on the support element and the light-absorbing particles are within the support element. The LED package may further comprise a second filter structure on the support element, the second filter structure configured to be more transmissive than reflective to a first wavelength band of light that passes through the first filter structure and more reflective than transmissive to other wavelengths of light that pass through the first filter structure. The LED package may further comprise a third filter structure on the support element, the third filter structure configured to be more transmissive than reflective to a second wavelength band of light that passes through the first filter structure and more reflective than transmissive to other wavelengths of light that pass through the first filter structure.

In another aspect, an LED package comprises: at least one LED chip configured to emit light with a first peak wavelength in a range from 430 nanometers (nm) to 480 nm; a lumiphoric material arranged to convert at least a portion of the light of the first peak wavelength to light with a second peak wavelength that is in a range from 700 nm to 4000 nm; and a filter structure on the lumiphoric material, the filter structure configured to be more reflective than transmissive to light having the first peak wavelength, the filter structure further configured to be more transmissive than reflective to a first wavelength band of light that is above the first peak wavelength and more reflective than transmissive to other wavelengths of light above the first peak wavelength. The LED package may further comprise light-absorbing particles configured to absorb a portion of the light with the second peak wavelength. In certain embodiments, the filter structure is further configured to be more transmissive than reflective to a second wavelength band of light that is above the first peak wavelength and more reflective than transmissive to other wavelengths of light outside the second wavelength band and above the first peak wavelength. In certain embodiments, the filter structure is further configured to be more transmissive than reflective to a third wavelength band of light that is above the first peak wavelength and more reflective than transmissive to other wavelengths of light outside the first wavelength band and the second wavelength band, and above the first peak wavelength. The LED package may further comprise a support element on the at least one LED chip, wherein the filter structure is on the support element.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of an exemplary light-emitting diode (LED) package according to principles of the present disclosure.

FIG. 2 is a cross-sectional view of an exemplary multiple-layer arrangement for the filter structure of FIG. 1 according to aspects of the present disclosure.

FIG. 3A is a cross-sectional view of a portion of an LED package including a cover structure with first and second filter structures on opposing sides of a support element.

FIG. 3B is a general transmission versus wavelength plot illustrating the relationship between the first and second filter structures of FIG. 3A.

FIG. 4 is a cross-sectional view of a portion of an LED package that is similar to the LED package of FIG. 3A for embodiments that further include infrared-absorbing particles.

FIG. 5A is a cross-sectional view of a portion of an LED package that is similar to the LED package of FIG. 3A for embodiments that further include a third filter structure.

FIG. 5B is a general transmission versus wavelength plot illustrating the relationship between the first, second, and third filter structures of FIG. 5A.

FIG. 6 is a cross-sectional view of a portion of an LED package that is similar to the LED package of FIG. 5A for embodiments that further include infrared-absorbing particles.

FIG. 7 is a cross-sectional view of a portion of an LED package that is similar to the LED package of FIG. 6 for an alternative arrangement of the first, second, and third filter structures.

FIG. 8A is a cross-sectional view of a portion of an LED package that is similar to the LED package of FIG. 5A for embodiments where the second filter structure is a multiple band-pass filter.

FIG. 8B is a general transmission versus wavelength plot illustrating the relationship between the first and second filter structures of FIG. 8A.

FIG. 9 is a cross-sectional view of a portion of an LED package that is similar to the LED package of FIG. 8A for embodiments that further include infrared-absorbing particles.

FIG. 10 is a cross-sectional view of a portion of an LED package that is similar to the LED package of FIG. 9 for an alternative arrangement of the first and second filter structures.

FIG. 11A is a cross-sectional view of a portion of an LED package that is similar to the LED package of FIG. 8A for embodiments where the first filter structure is formed with a complex reflection versus transmission structure.

FIG. 11B is a general transmission versus wavelength plot illustrating the transmission versus wavelength relationship for the first filter structure of FIG. 11A.

FIG. 12 is a transmission and reflectance plot illustrating simulation results for a dual band-pass filter formed in a single filter structure according to principles of the present disclosure.

FIG. 13 is a cross-sectional view of an LED package with a submount according to principles of the present disclosure.

FIG. 14 is a cross-sectional view of an LED package similar to the LED package of FIG. 13 with a lens formed on the submount according to principles of the present disclosure.

FIG. 15 is a cross-sectional view of an LED package similar to the LED package of FIG. 1 with an alternative arrangement of the lumiphoric material.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices and more particularly to infrared light-emitting diodes (LEDs) with filter structures. Filter structures include long-pass filters configured to pass wavelength-converted light while reflecting light from underlying LED chips. Filter structures further include various dual band-pass filters and multiple band-pass filters in combination with long-pass filters that provide targeted emissions in specific infrared wavelength bands. Filter structures may be provided as part of cover structures over LED chips as various multiple-layer dielectric layer sequences. Infrared light-absorbing particles may be provided in combination with filter structures to provide further targeted emissions.

An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may generally include an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that may include many materials, such as sapphire, silicon carbide (SiC), aluminum nitride (AlN), and GaN.

Different embodiments of the active LED structure may emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, spectral density, etc. In certain embodiments, lumiphoric materials having nonvisible peak wavelengths, such as infrared with peak wavelengths above 700 nm or above 800 nm, may be used. In certain embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In certain embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may comprise a generally planar upper surface that corresponds to a light emission area of the LED package. Wavelength conversion elements and cover structures may be attached to one or more LED chips using, for example, a layer of transparent adhesive. In various embodiments, wavelength conversion elements may comprise configurations such as phosphor-in-glass, ceramic phosphor plate, or single crystal phosphor arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that may be cut or separated into individual wavelength conversion elements.

The present disclosure may be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a submount or a lead frame structure.

Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

LED-based light sources are increasingly used for illumination in a variety of applications. Exemplary applications for infrared LED-based light sources include medical devices and/or health-related lighting devices, medical lighting, industrial applications, scientific applications, and/or security applications. Typical peak wavelengths for such applications are greater than 700 nm, or greater than 800 nm, or various ranges from 700 nm to 4000 nm, or 750 nm to 4000 nm, or 800 nm to 4000 nm. Some infrared LED devices may include active LED structures of LED chips that are configured to generate infrared wavelengths. For example, active LED structures based on aluminum gallium arsenide (AlGaAs) epitaxial structures may be configured to provide infrared multiple quantum well (MQW) emissions. While such infrared-emitting LED chips may have high radiant power, they may suffer from poor temperature control and increased current droop. Other infrared LED devices may include LED chips that emit visible light in combination with lumiphoric materials, such as phosphors, configured to provide wavelength conversion of the visible light to infrared. Such devices may provide better temperature control and current droop when GaN-based active LED structures are used. However, broader emission spectra as well as increased amounts of visible light in the overall spectral output relative to infrared emission may not be suitable for all applications. In some instances, secondary optics may be added at the LED fixture level that introduce absorption filters for reducing lower wavelength emissions. However, such filters at the fixture level can be bulky and expensive while also having a greater impact on overall brightness and efficiency.

According to aspects of the present disclosure, LED-based lighting devices are provided at the LED package level that use various combinations of LED chips emitting visible light, recipient lumiphoric materials that convert the visible light to infrared, and various filter structures configured to reduce visible light in the spectral output. In various examples, LED-based lighting devices include shorter wavelength LED chips that exhibit greater emission efficiency, such as various blue wavelengths (e.g., peak wavelengths in a range from 430 nm to 480 nm) with lumiphoric materials such as phosphors that convert blue wavelengths to emissions with peak wavelengths above 700 nm or above 800 nm. Integrated filter structures are included in LED packages that reduce emissions below certain wavelengths, such as below 500 nm or below 700 nm or below 800 nm. Accordingly, such LED packages may be readily incorporated in various lighting applications for infrared without the need for additional elements.

Infrared lumiphoric materials, such as infrared phosphors, may have reduced wavelength conversion efficiency compared with lumiphoric materials that provide visible light, thereby increasing associated costs and/or performance. By providing filter structures proximate LED chips and within individual LED packages, emission efficiency may be increased while also providing drop-in light sources for larger fixtures. For example, visible light reflected by filter structures may have multiple passes through infrared lumiphoric materials, thereby increasing conversion efficiency and/or reducing amounts of infrared lumiphoric materials needed. With reduced amounts of infrared lumiphoric materials, thermal performance is improved due to reduced heating. Moreover, reducing and/or excluding visible light from the spectral output may reduce false signals and related noise in infrared detector applications.

As used herein, filter structures may include multiple layers or coatings with variable thickness and/or index of refraction differences that collectively provide the ability to pass certain wavelengths of light while reflecting or otherwise redirecting other wavelengths of light. In various arrangements, filter structures as described herein may include one or more of a high-pass filter structure or a long-pass filter structure configured to promote wavelengths above 500 nm, or above 700 nm, or above 800 nm to pass through while reflecting lower wavelengths. Filter structures may further include short-pass filters that reflect higher infrared wavelengths and/or multiple-band filters in combination with the long-pass filters that effectively narrow or tune infrared wavelength emissions in the overall spectral output.

By way of non-limiting example, a filter structure may include alternating layers with alternating index of refraction materials (e.g., high-low) where relative layer thicknesses are chosen specifically to promote constructive interference for wavelengths above or below a specific wavelength or for a specific wavelength band while reflecting other wavelengths. Filter structures according to the present disclosure may include but are not limited to one or more oxides of silicon (e.g., SiO₂), oxides of zirconium (e.g., ZrO₂), oxides of aluminum (e.g., Al₂O₃), oxides of titanium (e.g., TiO₂ or Ti₃O₅), oxides of tantalum (e.g., Ta₂O₅), oxides of indium (e.g., In₂O₃), indium tin oxide (ITO), silicon nitride (e.g., SiNₓ), magnesium fluoride (e.g., MgF₂), cerium fluoride (e.g., CeF₃), lanthanum fluoride (e.g., LaF₃), aluminum fluoride (e.g., AlF₃) fluoropolymers, and combinations thereof. Specific arrangements of filter structures in LED packages are disclosed that may promote reflection of unconverted light (e.g., from an LED chip) back into lumiphoric materials within increased efficiency across multiple emission angles.

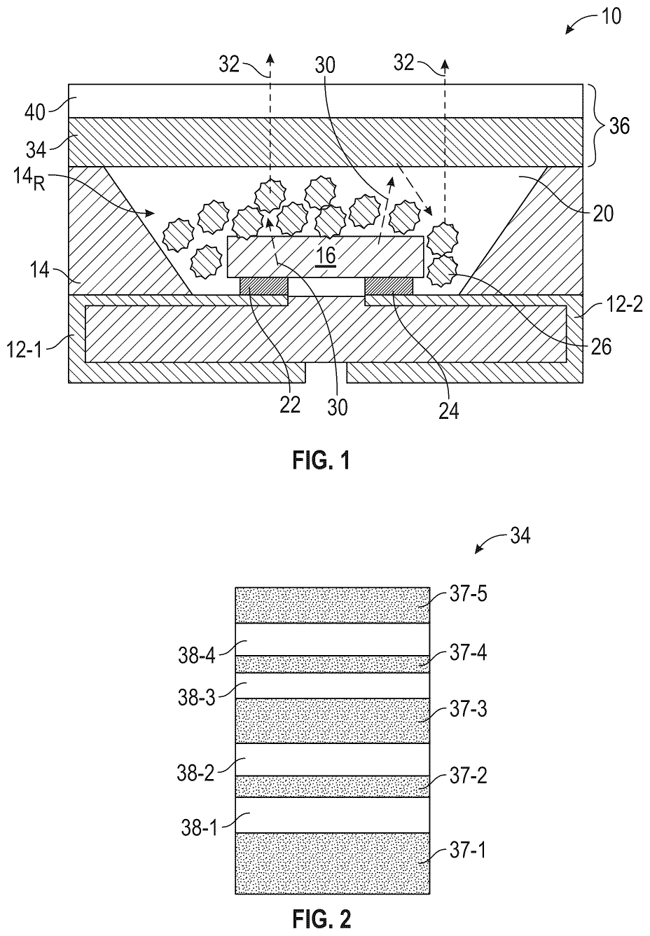

FIG. 1 is a cross-sectional view of an exemplary LED package 10 according to principles of the present disclosure. The LED package 10 includes a lead frame structure collectively formed by a plurality of leads 12-1 and 12-2, a body or housing 14 that encases a portion of the lead frame structure, and a recess 14R formed by the housing 14. As illustrated, an LED chip 16 is flip-chip mounted on the leads 12-1 and 12-2 and an encapsulant 20 may at least partially fill the recess 14R, thereby covering the LED chip 16. For flip-chip mounting, anode and cathode pads 22, 24 of the LED chip 16 may be respectively attached to the leads 12-1 and 12-2 by way of bonding material, such as a solder attach material. While a flip-chip arrangement is shown, the principles described are also applicable to other configurations, such as the presence of one or more wire bonds for electrically connecting the LED chip 16 to one or more of the leads 12-1 and 12-2. Moreover, while a single LED chip 16 is illustrated, the principles are also applicable to embodiments that include multiple LED chips 16 connected to the leads 12-1 and 12-2. In the alternative, multiple LED chips 16 may each be separately connected to different pairs of leads from the lead frame structure to provide individual control. In still further embodiments, the principles described are also applicable for embodiments where the support structure of the LED package 10 is a submount structure instead of a lead frame structure.

The LED package 10 may include a lumiphoric material 26 positioned to receive light of a first peak wavelength 30 from the LED chip 16 and provide light of a second peak wavelength 32 by wavelength conversion. In an exemplary embodiment where the LED package 10 provides infrared emissions, the light of the first peak wavelength 30 is in a range from 430 nm to 480 nm and the light of the second peak wavelength 32 is in above 700 nm, or above 750 nm, or above 800 nm, or in a range from 700 nm to 4000 nm, or 750 nm to 4000 nm, or 800 nm to 4000 nm. In certain embodiments, the lumiphoric material 26 embodies phosphor particles that are distributed or otherwise suspended in the encapsulant 20. In other embodiments, the lumiphoric material 26 may be deposited or otherwise formed as a layer on the LED chip 16.

The LED package 10 further includes a filter structure 34 positioned to reduce amounts of the light of the first peak wavelength 30 from escaping the LED package 10. In certain embodiments, the filter structure 34 may include a long-pass filter that passes the light of the second peak wavelength 32 while reflecting the light of the first peak wavelength 30. As illustrated, light of the first peak wavelength 30 that is reflected back may have increased opportunities to interact with the lumiphoric material 26 and be subject to wavelength conversion. In other embodiments, the filter structure 34 may embody a combination filter that includes a long-pass filter and a short-pass filter where the long-pass filter reflects back light of the first peak wavelength 30 and the short-pass filter provides a cut-off for the longer wavelengths exiting the LED package as the second peak wavelength 32. Such a filter structure 34 may be referred to as a band-pass filter. Moreover, the filter structure 34 may form a dual band-pass filter or a multiple band-pass filter in further embodiments. The ability to target certain wavelengths and/or wavelength bands above 700 nm provides targeted emissions for specific applications, such as specific infrared wavelengths matched to biological absorptions of various tissues. The filter structure 34 may be integrated as part of a cover structure 36 of the LED package 10. The cover structure 36 may include a support element 40 that is generally light transparent, and the filter structure 34 may be formed as a layer on the support element 40.

FIG. 2 is a cross-sectional view of an exemplary multiple-layer arrangement for the filter structure 34 of FIG. 1 according to aspects of the present disclosure. In FIG. 2, the filter structure 34 includes a plurality of first dielectric layers 37-1 to 37-5 in an alternating arrangement with a plurality of second dielectric layers 38-1 to 38-4. In certain embodiments, the first dielectric layer 37-1 of the plurality of first dielectric layers 37-1 to 37-5 is positioned closest to the LED chip (i.e., 16 of FIG. 1) and forms a light entrance side of the filter structure 34 while a fifth dielectric layer 37-5 of the plurality of first dielectric layers 37-1 to 37-5 is positioned farthest from the LED chip (i.e., 16 of FIG. 1) and thereby forms a light exit side of the filter structure 34. In certain embodiments, the first dielectric layers 37-1 to 37-5 include a first material that is different from a second material of the second dielectric layers 38-1 to 38-4 to form index of refraction steps therebetween. By way of example, the first dielectric layers 37-1 to 37-5 may comprise TiO₂ and the second dielectric layers 38-1 to 38-4 may comprise MgF₂. The first dielectric layer 37-1 that is closest to the lumiphoric material (i.e., 26 of FIG. 1) may have an index of refraction that is more closely matched to silicone, which is typically used as a binder for lumiphoric materials and/or for the encapsulant (i.e., 20 of FIG. 1), and the first dielectric layer 37-5 that is closest to the support element (i.e., 40 of FIG. 1) may have an index of refraction more closely matched to the material of the support element, such as glass. Accordingly, an interface between the first dielectric layer 37-1 and underlying lumiphoric material and/or encapsulant may be configured to permit light to pass into the filter structure 34, and an interface between the first dielectric layer 37-5 and the support element may be configured to permit light that is not reflected within the filter structure 34 to pass.

As further illustrated in FIG. 2, the first dielectric layers 37-1 to 37-5 have varying thicknesses and the second dielectric layers 38-1 to 38-4 have varying thicknesses to promote increased reflection at different angles of incidence. While nine total layers are illustrated, the filter structure 34 may include various numbers of layers, such as in a range from eight layers to twenty-five layers, among others. Specific configurations may tailor light entrance and/or light exit portions of the filter structure 34 for more closely matched indexes of refractions with interfaces to the filter structure 34. Moreover, middle portions of the filter structure 34 may be configured to preferentially reflect or transmit certain wavelengths or wavelength bands of infrared emissions.

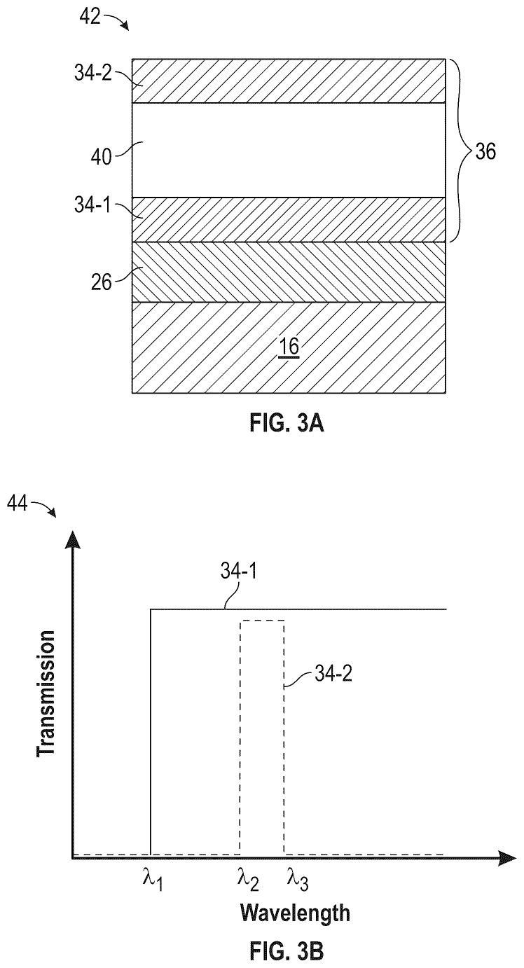

FIG. 3A is a cross-sectional view of a portion of an LED package 42 including a cover structure 36 with first and second filter structures 34-1, 34-2 on opposing sides of the support element 40. In FIG. 3A, the lumiphoric material 26 is generally illustrated between the cover structure 36 and the LED chip 16. In certain embodiments, the lumiphoric material 26 may be separately formed on the LED chip 16 as illustrated in FIG. 1 or as a blanket-deposited layer on the LED chip 16. In other embodiments, the lumiphoric material may be formed on the cover structure 36 before the cover structure 36 is mounted in place on the LED chip 16. In certain embodiments, the first filter structure 34-1 embodies a long-pass filter configured to be more reflective than transmissive to light of a first peak wavelength emitted by the LED chip 16, such as in a range from 430 nm to 480 nm. As indicated above with respect to FIG. 1, such an arrangement may promote increased interactions with the lumiphoric material 26 for increased wavelength conversion. The second filter structure 34-2 may embody a single band-pass filter configured to be transmissive to a specific wavelength band of light that passes through the first filter structure 34-1. In certain embodiments, the support element 40 is provided between the first and second filter structures 34-1, 34-2. The support element 40 is generally light-transmissive to light from the LED chip 16 and the lumiphoric material 26. Accordingly, light exiting the first filter structure 34-1 may readily pass through the support element 40 to reach the second filter structure 34-2. Moreover, the thickness of the support element 40 provides physical separation between the first and second filter structures 34-1, 34-2 to promote improved light guiding, light mixing, color over angle uniformity, and/or enhanced light-guiding of high angle light. Exemplary thickness values for the support element 40 that provide such light characteristics are a range from 100 microns (μm) to 600 μm or a range from 100 μm to 150 μm.

FIG. 3B is a general transmission versus wavelength plot 44 illustrating the relationship between the first and second filter structures 34-1, 34-2 of FIG. 3A. The x-axis represents relative wavelength that increases with distance from the origin, and the y-axis represents transmission that increases with distance from the origin. Accordingly, a point on the x-axis with no value on the y-axis represents a wavelength that is reflected. As illustrated, the first filter structure 34-1 may embody a long-pass filter for light at or above a first wavelength λ₁. The first wavelength λ₁ may be set at a value to promote reflection of light from the LED chip (i.e., 16 of FIG. 3A) back into the lumiphoric material (i.e., 26 of FIG. 3A). The second filter structure 34-2 may embody a single band-pass filter that preferentially passes light in a first wavelength band defined from a second wavelength λ₂ to a third wavelength λ₃, while reflecting other wavelengths above the first wavelength λ₁ that passes through the first filter structure 34-1.

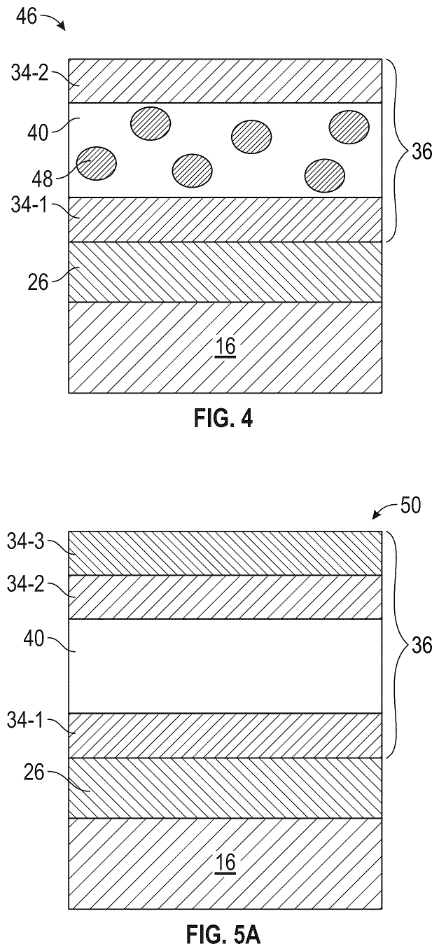

FIG. 4 is a cross-sectional view of a portion of an LED package 46 that is similar to the LED package 42 of FIG. 3A for embodiments that further include infrared-absorbing particles 48. The infrared-absorbing particles 48 are provided in a light path between the LED chip 16 and a primary light-emitting surface of the LED package 46 formed by a top surface of the cover structure 36. The infrared-absorbing particles 48 are configured to absorb one or more target wavelengths of light that pass through the first filter structure 34-1 and not the second filter structure 34-2. Accordingly, the infrared-absorbing particles 48 may beneficially remove light that is not intended to exit the LED package 46. In certain embodiments, the infrared-absorbing particles 48 may comprise doped tungsten oxides, doped tin oxides, and/or lanthanum hexaboride. With reference back to FIG. 3B, the infrared-absorbing particles 48 may be configured to absorb light that is between the first wavelength λ₁ and the second wavelength λ₂, and/or light that is above the third wavelength λ₃. The light-guiding and/or mixing principles described above for the support element 40 may promote increased interactions with the infrared-absorbing particles 48 for improved absorption of targeted wavelengths.

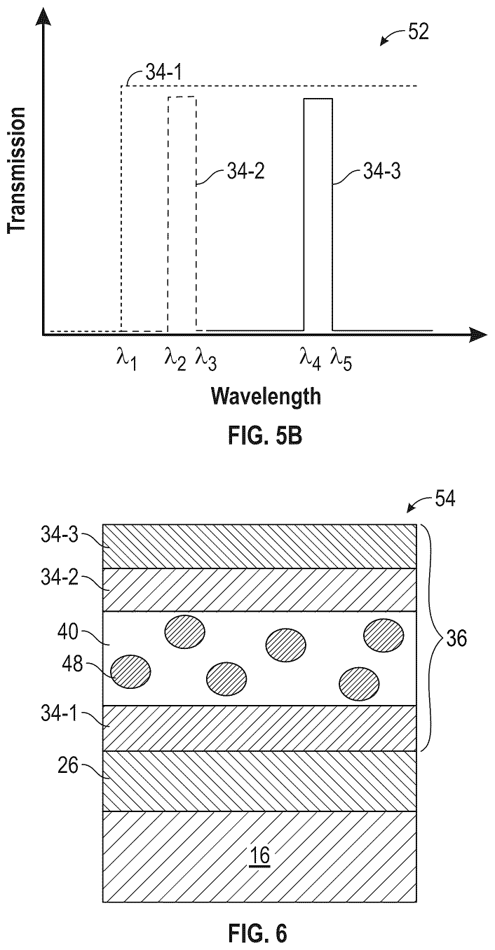

FIG. 5A is a cross-sectional view of a portion of an LED package 50 that is similar to the LED package 42 of FIG. 3A for embodiments that further include a third filter structure 34-3. As illustrated, the third filter structure 34-3 may be integrated with the cover structure 36. In certain embodiments, the second and third filter structures 34-2, 34-3 are positioned on a same side of the cover structure 36 opposite the first filter structure 34-1. Accordingly, the thickness of the support element 40 may promote improved light guiding, light mixing, color over angle uniformity, and/or enhanced light-guiding of high angle light leaving the first filter structure 34-2 before interacting with the second and/or third filter structures 34-2, 34-3. The third filter structure 34-3 may embody another single band-pass filter that preferentially passes light in a second wavelength band defined from a fourth wavelength λ₄ to a fifth wavelength λ₅, while reflecting other wavelengths above the first wavelength λ₁ that passes through the first filter structure 34-1. The second and third filter structures 34-2, 34-3 may be positioned proximate one another to work in tandem and reflect light outside the first and second wavelength bands. The second and third filter structures 34-2, 34-3 may be positioned in direct contact with one another. In certain embodiments, the second and third filter structures 34-2, 34-3 may be integrated and/or intermixed together as a continuous multiple layer structure. In such cases, the second and third filter structures 34-2, 34-3 may alternatively be referred to as single filter structure (e.g., the second filter structure 34-2) that is a dual band-pass filter structure.

FIG. 5B is a general transmission versus wavelength plot 52 illustrating the relationship between the first, second, and third filter structures 34-1 to 34-3 of FIG. 5A. The x-axis represents relative wavelength that increases with distance from the origin, and the y-axis represents transmission that increases with distance from the origin. Accordingly, a point on the x-axis with no value on the y-axis represents a wavelength that is reflected. As illustrated, the first filter structure 34-1 may embody a long-pass filter for light at or above the first wavelength λ₁. The first wavelength λ₁ may be set at a value to promote reflection of light from the LED chip (i.e., 16 of FIG. 5A) back into the lumiphoric material (i.e., 26 of FIG. 5A). The second filter structure 34-2 may embody a single band-pass filter that preferentially passes light in a first wavelength band defined from a second wavelength λ₂ to a third wavelength λ₃, while reflecting other wavelengths above the first wavelength λ₁ that passes through the first filter structure 34-1. The third filter structure 34-3 may embody another single band-pass filter that preferentially passes light in a second wavelength band defined from a fourth wavelength λ₄ to a fifth wavelength λ₅, while reflecting other wavelengths above the first wavelength λ₁ that passes through the first filter structure 34-1.

FIG. 6 is a cross-sectional view of a portion of an LED package 54 that is similar to the LED package 50 of FIG. 5A for embodiments that further include infrared-absorbing particles 48. The infrared-absorbing particles 48 are configured to absorb one or more target wavelengths of light that pass through the first filter structure 34-1 and are reflected by the second and third filter structures 34-2, 34-3. Accordingly, the infrared-absorbing particles 48 may beneficially remove light that is not intended to exit the LED package 54. As described above, the infrared-absorbing particles 48 may comprise doped tungsten oxides, doped tin oxides, and/or lanthanum hexaboride. With reference back to FIG. 5B, the infrared-absorbing particles 48 may be configured to absorb light that is between the first wavelength λ₁ and the second wavelength λ₂, and/or light that is between the third wavelength λ₃ and the fourth wavelength λ₄, and/or light that is above the fifth wavelength λ₅.

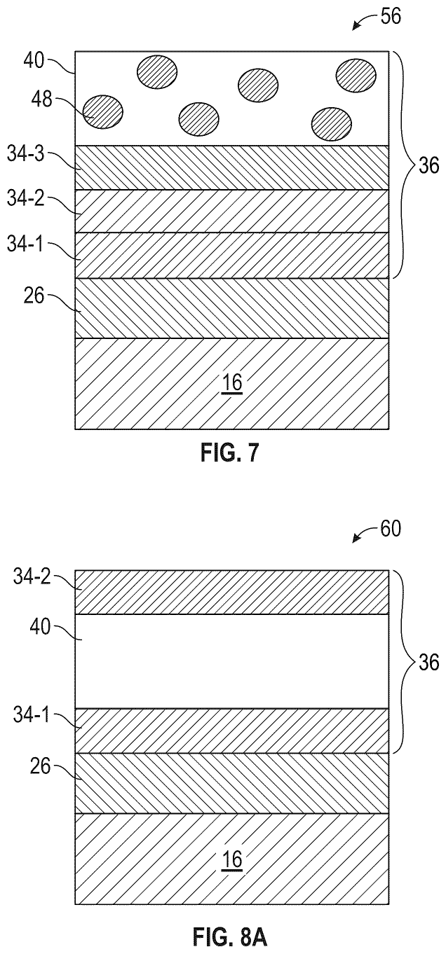

FIG. 7 is a cross-sectional view of a portion of an LED package 56 that is similar to the LED package 54 of FIG. 6 for an alternative arrangement of the first, second, and third filter structures 34-1 to 34-3. As illustrated, the first, second, and third filter structures 34-1 to 34-3 may all be positioned on a same side of the support element 40. Accordingly, light entering the support element 40 may have already passed through each of the first, second, and third filter structures 34-1 to 34-3. Additionally, the infrared-absorbing particles 48 may further be positioned within the support element 40. With such an arrangement, the infrared-absorbing particles 48 may be positioned to absorb targeted wavelengths before exiting the LED package 56. Moreover, the light-guiding and/or mixing principles of the support element 40 may promote increased absorption of targeted wavelengths.

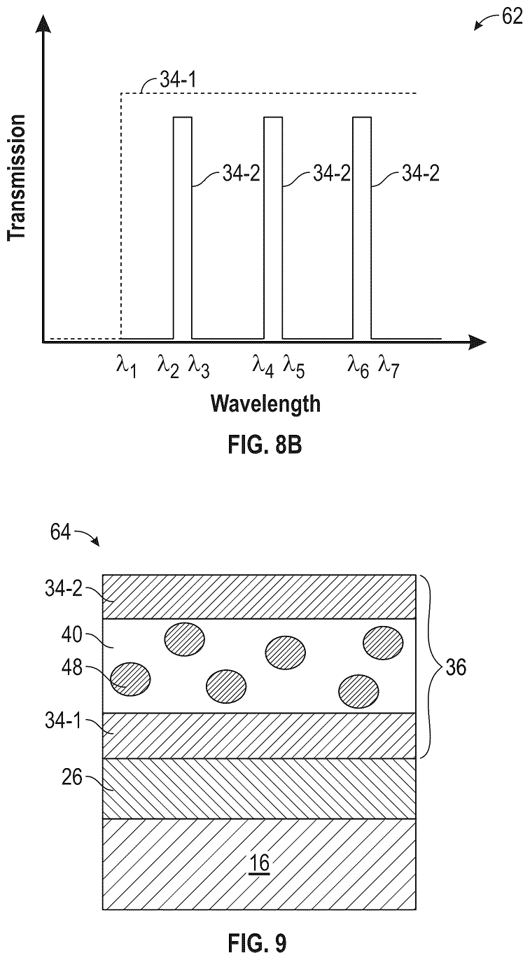

FIG. 8A is a cross-sectional view of a portion of an LED package 60 that is similar to the LED package 50 of FIG. 5A for embodiments where the second filter structure 34-2 is a multiple band-pass filter. The second filter structure 34-2 is configured to be transmissive to multiple wavelength bands of light that pass through the first filter structure 34-1. For example, the second filter structure 34-2 may be configured to pass first and second distinct wavelength bands of light or first, second, and third distinct wavelength bands of light. In certain embodiments, the first, second, and third distinct wavelength bands may be different wavelength bands of infrared light, although other wavelengths, including visible, are also contemplated. As with other embodiments, the first and second filter structures 34-1, 34-2 are on opposing sides of the support element 40. The thickness of the support element 40 provides physical separation between the first and second filter structures 34-1, 34-2 to promote improved light guiding, light mixing, color over angle uniformity, and/or enhanced light-guiding of high angle light.

FIG. 8B is a general transmission versus wavelength plot 62 illustrating the relationship between the first and second filter structures 34-1 and 34-2 of FIG. 8A. The x-axis represents relative wavelength that increases with distance from the origin, and the y-axis represents transmission that increases with distance from the origin. Accordingly, a point on the x-axis with no value on the y-axis represents a wavelength that is reflected. As illustrated, the first filter structure 34-1 may embody a long-pass filter for light at or above the first wavelength λ₁. The first wavelength λ₁ may be set at a value to promote reflection of light from the LED chip (i.e., 16 of FIG. 8A) back into the lumiphoric material (i.e., 26 of FIG. 8A). The second filter structure 34-2 may embody a multiple band-pass filter that preferentially passes light in multiple wavelength bands that are above the first wavelength λ₁. In the example of FIG. 8B, the second filter structure 34-2 passes light in a first wavelength band defined from a second wavelength λ₂ to a third wavelength λ₃, a second wavelength band defined from a fourth wavelength λ₄ to a fifth wavelength λ₄, and a third wavelength band defined from a sixth wavelength λ₆ to a seventh wavelength λ₇ while reflecting other wavelengths above the first wavelength λ₁ that pass through the first filter structure 34-1. As such, the second filter structure 34-2 may embody a multiple band-pass filter or a so-called comb filter.

FIG. 9 is a cross-sectional view of a portion of an LED package 64 that is similar to the LED package 60 of FIG. 8A for embodiments that further include infrared-absorbing particles 48. The infrared-absorbing particles 48 are configured to absorb one or more target wavelengths of light that pass through the first filter structure 34-1 and are reflected by the second filter structure 34-2. Accordingly, the infrared-absorbing particles 48 may beneficially remove light that is not intended to exit the LED package 64. As described above, the infrared-absorbing particles 48 may comprise doped tungsten oxides, doped tin oxides, and/or lanthanum hexaboride. With reference back to FIG. 8B, the infrared-absorbing particles 48 may be configured to absorb light that is between the first wavelength λ₁ and the second wavelength λ₂, and/or light that is between the third wavelength λ₃ and the fourth wavelength λ₄, and/or light that is between the fifth wavelength λ₅ and the sixth wavelength λ₆, and/or light that is above the seventh wavelength λ₇.

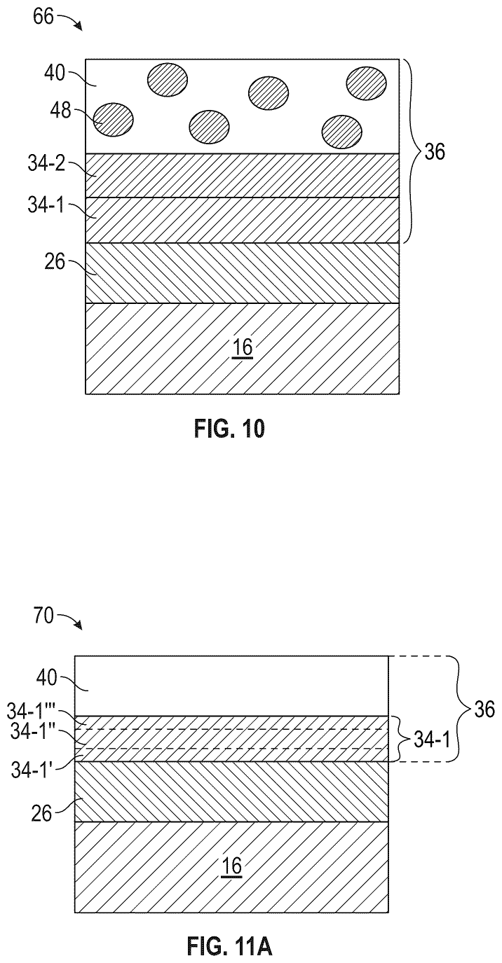

FIG. 10 is a cross-sectional view of a portion of an LED package 66 that is similar to the LED package 64 of FIG. 9 for an alternative arrangement of the first and second filter structures 34-1 and 34-2. As illustrated, the first and second filter structures 34-1 and 34-2 may both be positioned on a same side of the support element 40. Accordingly, light entering the support element 40 may have already passed through both the first and second filter structures 34-1 and 34-2. Additionally, the infrared-absorbing particles 48 may further be positioned within the support element 40. With such an arrangement, the infrared-absorbing particles 48 may be positioned to absorb targeted wavelengths before exiting the LED package 66.

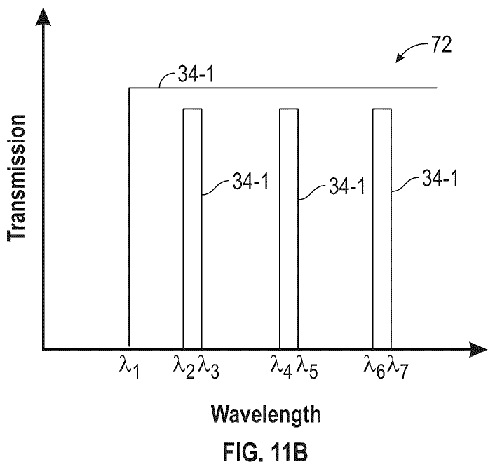

FIG. 11A is a cross-sectional view of a portion of an LED package 70 that is similar to the LED package 60 of FIG. 8A for embodiments where the first filter structure 34-1 is formed with a complex reflection versus transmission structure. For example, the first filter structure 34-1 of FIG. 11A may be configured as both a long-pass filter and a band-pass filter, such as a combination of the first and second filter structures 34-1, 34-2 of FIG. 3B. In another example, the first filter structure 34-1 of FIG. 11A may be configured as both a long-pass filter and a dual band-pass filter, such as a combination of the first, second, and third filter structures 34-1 to 34-3 of FIG. 5B. In another example, the first filter structure 34-1 of FIG. 11A may be configured as both a long-pass filter and a multiple band-pass filter, such as a combination of the first and second filter structures 34-1, 34-2 of FIG. 8B. Combining the various filtering structures into a single multiple-layer sequence of the first filter structure 34-1 may provide more simplified fabrication and/or reduced reflections for various wavelength bands from separate filter structures. In certain embodiments, a first region 34-1′ of the first filter structure 34-1 that is closest to the lumiphoric material 26 may be configured as a long-pass filter that promotes reflection of light from the LED chip 16 back into the lumiphoric material 26 while passing wavelength-converted light from the lumiphoric material 26. A second region 34-1″ and/or a third region 34-1′″ may then be configured as a band-pass filter, a dual band-pass filter, a multiple band-pass filter, and combinations thereof. In other embodiments, the first filter structure 34-1 may not necessarily have various distinct regions such that filtering structures are intermixed throughout. By way of example, the second region 34-1″ and the third region 34-1′″ may be combined in certain embodiments. In further embodiments, the light-absorbing particles 48 of FIG. 8A may be arranged within the support element 40 of FIG. 11A.

FIG. 11B is a general transmission versus wavelength plot 72 illustrating the transmission versus wavelength relationship for the first filter structure 34-1 of FIG. 11A. The x-axis represents relative wavelength that increases with distance from the origin, and the y-axis represents transmission that increases with distance from the origin. Accordingly, a point on the x-axis with no value on the y-axis represents a wavelength that is reflected. As illustrated, the first filter structure 34-1 may embody a long-pass filter for light at or above the first wavelength λ₁. The first wavelength λ₁ may be set at a value to promotes reflection of light from the LED chip (i.e., 16 of FIG. 11A) back into the lumiphoric material (i.e., 26 of FIG. 1A). The first filter structure 34-1 may further embody a multiple band-pass filter that preferentially passes light in multiple wavelength bands that are above the first wavelength λ₁. In the example of FIG. 11B, the first filter structure 34-1 passes light in a first wavelength band defined from a second wavelength λ₂ to a third wavelength λ₃, a second wavelength band defined from a fourth wavelength λ₄ to a fifth wavelength λ₄, and a third wavelength band defined from a sixth wavelength λ₆ to a seventh wavelength λ₇ while reflecting other wavelengths above the first wavelength λ₁ that pass through the first filter structure 34-1. As such, the first filter structure 34-1 may embody a long-pass filter in combination with a multiple band-pass filter.

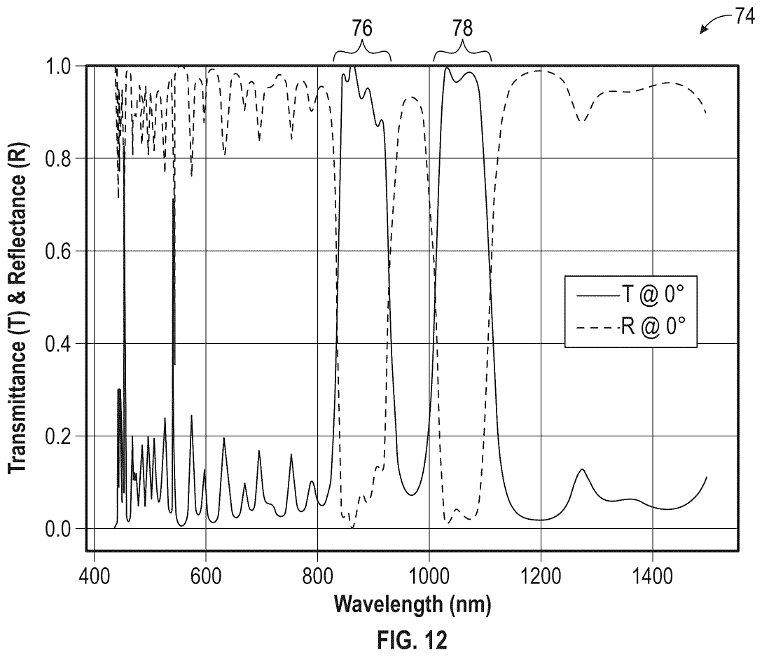

FIG. 12 is a transmission and reflectance plot 74 illustrating simulation results for a dual band-pass filter formed in a single filter structure according to principles of the present disclosure. As mentioned above, multiple transmission and reflectance structures may be intermixed within a multiple layer sequence of a single filter structure. In this manner, the simulation results provided by FIG. 12 may be implemented as the second filter structure 34-2 of FIGS. 8A and 8B, or as a portion of the first filter structure 34-1 of FIGS. 11A and 11B. The simulation was based on a filter structure similar to FIG. 2 for embodiments with seventeen total layers of alternating materials. Specifically, the seventeen total layers alternated between first dielectric layers of TiO₂ and second dielectric layers of MgF₂. The relative thicknesses of each layer are different through the seventeen layers. A thickest overall dielectric layer is positioned at a light entrance side of the simulated filter structure and a second thickest dielectric layer is positioned between other dielectric layers. As illustrated, the simulated results exhibit a first wavelength band 76 and a second wavelength band 78 that provided band-pass transmissions above 800 nm, well into the infrared spectrum. The first and second wavelength bands 76, 78 form distinct transmission bands that are separated by a range of wavelengths that are generally reflected.

LED packages described above with respect to FIGS. 1 to 12 may be arranged in a variety of form factors. Exemplary LED packages may include arrangements of one or more elements, such as lumiphoric materials, encapsulants, light-altering materials, lenses, and electrical contacts, among others, that are provided with one or more LED chips. In certain aspects, an LED package may include a support member, such as a submount or a lead frame structure. While each of the embodiments described herein are provided in the context of an LED chip, the principles described are applicable to LED packages with multiple LED chips.

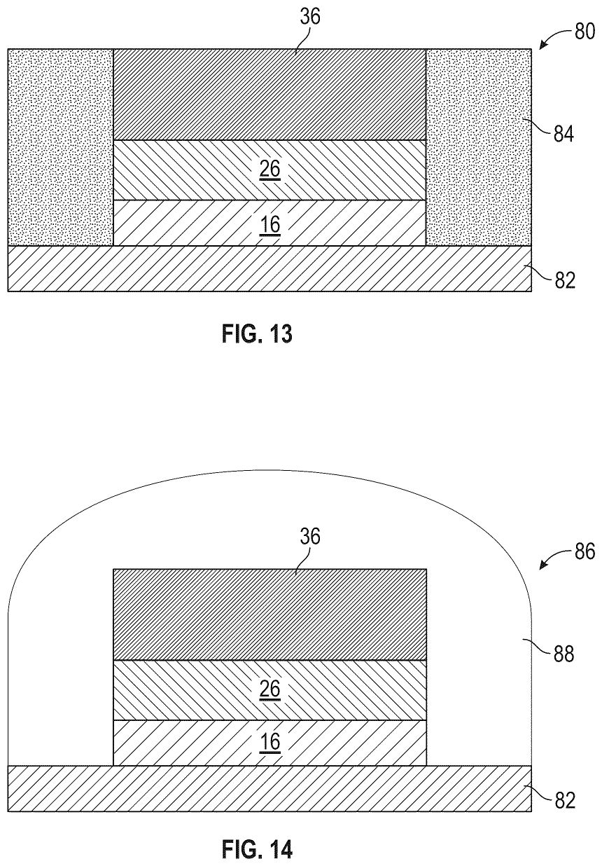

FIG. 13 is a cross-sectional view of an LED package 80 with a submount 82 according to principles of the present disclosure. The submount 82 may embody a generally planar structure with electrically conductive traces for receiving the LED chip 16. As illustrated, the lumiphoric material 26 and the cover structure 36 are provided on the LED chip 16. The cover structure 36 may include any of the filter structures described above with respect to FIGS. 1 to 12. In certain embodiments, a light-altering material 84, such as a light-reflective material, may be arranged on the submount 82 and adjacent the LED chip 16, the lumiphoric material 26, and the cover structure 36. When light-reflective, the light-altering material 84 is configured to increase reflections of laterally propagating light toward an intended emission direction through a top surface of the cover structure 36.

FIG. 14 is a cross-sectional view of an LED package 86 similar to the LED package 80 of FIG. 13 with a lens 88 formed on the submount 82 according to principles of the present disclosure. The lens 88 may be formed with a shape, such as a curved upper surface, that effectively shapes an emission pattern of light exiting the LED package 86. Exemplary shapes for the lens 88 include hemispheric, ellipsoid, ellipsoid bullet, cubic, flat, hex-shaped and square. In certain embodiments, a suitable shape includes both curved and planar surfaces, such as a hemispheric or curved top portion with planar side surfaces. The cover structure 36 may include any of the filter structures described above with respect to FIGS. 1 to 12.

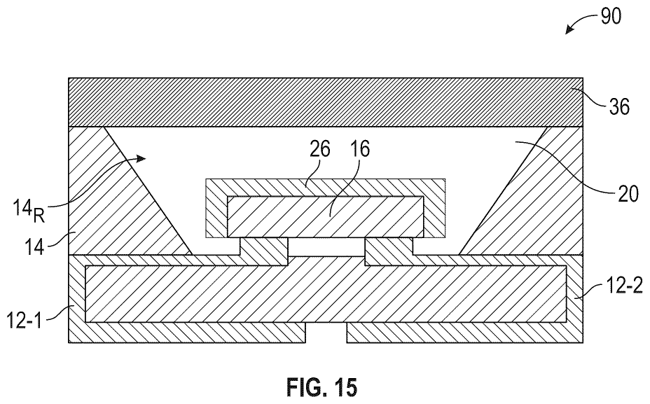

FIG. 15 is a cross-sectional view of an LED package 90 similar to the LED package 10 of FIG. 1 with an alternative arrangement of the lumiphoric material 26. In FIG. 15, the lumiphoric material 26 embodies a conformal coating on the LED chip 16. The remainder of the encapsulant 20 may provide separation with the cover structure 36. The cover structure 36 may include any of the filter structures described above with respect to FIGS. 1 to 12.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
at least one LED chip configured to emit light with a first peak wavelength in a range from 430 nanometers (nm) to 480 nm;
a lumiphoric material arranged to convert at least a portion of the light of the first peak wavelength to light with a second peak wavelength that is in a range from 700 nm to 4000 nm;
a first filter structure on the lumiphoric material, the first filter structure configured to be more reflective than transmissive to light having the first peak wavelength and more transmissive than reflective to light having the second peak wavelength; and
a second filter structure on the first filter structure, the second filter structure configured to be more transmissive than reflective to a first wavelength band of light that passes through the first filter structure and more reflective than transmissive to other wavelengths of light that pass through the first filter structure.

2. The LED package of claim 1, further comprising a support element on the at least one LED chip, wherein the first filter structure and the second filter structure are on opposing sides of the support element.

3. The LED package of claim 2, wherein the first filter structure and the second filter structure are separated by a thickness of the support element, and wherein the thickness of the support element is in a range from 100 microns (μm) to 600 μm.

4. The LED package of claim 2, wherein the support element comprises light-absorbing particles that absorb a portion of the light with the second peak wavelength that is outside of the first wavelength band.

5. The LED package of claim 4, wherein the light-absorbing particles comprise at least one of doped tungsten oxide, doped tin oxide, and lanthanum hexaboride.

6. The LED package of claim 2, further comprising a third filter structure on a same side of the support element as the second filter structure, the third filter structure configured to be more transmissive than reflective to a second wavelength band of light that passes through the first filter structure and more reflective than transmissive to other wavelengths of light outside the second wavelength band that pass through the first filter structure.

7. The LED package of claim 1, wherein the second filter structure is further configured to be more transmissive than reflective to a second wavelength band of light that passes through the first filter structure and more reflective than transmissive to other wavelengths of light that are outside the first wavelength band and the second wavelength band.

8. The LED package of claim 7, wherein the second filter structure is further configured to be more transmissive than reflective to a third wavelength band of light that passes through the first filter structure and more reflective than transmissive to other wavelengths of light that are outside the first wavelength band, the second wavelength band, and the third wavelength band.

9. The LED package of claim 1, further comprising a support element on the at least one LED chip, wherein the first filter structure and the second filter structure are on a same side of the support element.

10. The LED package of claim 9, further comprising a third filter structure on the same side of the support element as the first filter structure and the second filter structure, the third filter structure configured to be more transmissive than reflective to a second wavelength band of light that passes through the first filter structure and more reflective than transmissive to other wavelengths of light that pass through the first filter structure.

11. A light-emitting diode (LED) package comprising:
at least one LED chip configured to emit light with a first peak wavelength in a range from 430 nanometers (nm) to 480 nm;
a lumiphoric material arranged to convert at least a portion of the light of the first peak wavelength to light with a second peak wavelength that is in a range from 700 nm to 4000 nm;
a first filter structure on the lumiphoric material, the first filter structure configured to be more reflective than transmissive to light having the first peak wavelength and more transmissive than reflective to light having the second peak wavelength; and
light-absorbing particles configured to absorb a portion of the light with the second peak wavelength.

12. The LED package of claim 11, further comprising an encapsulant on the at least one LED chip, wherein the light-absorbing particles are within the encapsulant.

13. The LED package of claim 11, further comprising a support element on the at least one LED chip, wherein the first filter structure is on the support element and the light-absorbing particles are within the support element.

14. The LED package of claim 13, further comprising a second filter structure on the support element, the second filter structure configured to be more transmissive than reflective to a first wavelength band of light that passes through the first filter structure and more reflective than transmissive to other wavelengths of light that pass through the first filter structure.

15. The LED package of claim 14, further comprising a third filter structure on the support element, the third filter structure configured to be more transmissive than reflective to a second wavelength band of light that passes through the first filter structure and more reflective than transmissive to other wavelengths of light that pass through the first filter structure.

16. A light-emitting diode (LED) package comprising:
at least one LED chip configured to emit light with a first peak wavelength in a range from 430 nanometers (nm) to 480 nm;
a lumiphoric material arranged to convert at least a portion of the light of the first peak wavelength to light with a second peak wavelength that is in a range from 700 nm to 4000 nm; and
a filter structure on the lumiphoric material, the filter structure configured to be more reflective than transmissive to light having the first peak wavelength, the filter structure further configured to be more transmissive than reflective to a first wavelength band of light that is above the first peak wavelength and more reflective than transmissive to other wavelengths of light above the first peak wavelength.

17. The LED package of claim 16, further comprising light-absorbing particles configured to absorb a portion of the light with the second peak wavelength.

18. The LED package of claim 16, wherein the filter structure is further configured to be more transmissive than reflective to a second wavelength band of light that is above the first peak wavelength and more reflective than transmissive to other wavelengths of light outside the second wavelength band and above the first peak wavelength.

19. The LED package of claim 18, wherein the filter structure is further configured to be more transmissive than reflective to a third wavelength band of light that is above the first peak wavelength and more reflective than transmissive to other wavelengths of light outside the first wavelength band and the second wavelength band, and above the first peak wavelength.

20. The LED package of claim 16, further comprising a support element on the at least one LED chip, wherein the filter structure is on the support element.
